(19) United States
(12) Patent Application Publication
(10) Pub. No.: US 2012/0218019 A1
(43) Pub. Date: Aug. 30, 2012

(54) INTERNAL VOLTAGE GENERATING CIRCUIT AND TESTING METHOD OF INTEGRATED CIRCUIT USING THE SAME

(76) Inventors: Kang-Seol LEE, Gyeonggi-do (KR); Sang-Mook Oh, Gyeonggi-do (KR)

(21) Appl. No.: 13/117,045

(22) Filed: May 26, 2011

(30) Foreign Application Priority Data
Feb. 28, 2011 (KR) 10-2011-0017938

(51) Int. Cl. H03L 5/00; H02J 1/00

(52) U.S. Cl. 327/331

(57) ABSTRACT

An internal voltage generating circuit of a semiconductor device includes a normal reference voltage generating unit configured to generate a normal reference voltage having a constant voltage level without regard to PVT variations, a test reference voltage generating unit configured to generate a test reference voltage by dividing a voltage level between an external power supply voltage and the normal reference voltage at a set ratio, an operation reference voltage generating unit configured to generate an operation reference voltage by selecting one of the normal reference voltage and the test reference voltage in response to a test signal, and an internal voltage generating unit configured to generate an internal voltage whose voltage level is determined based on the level of the operation reference voltage.

### CROSS-REFERENCE TO RELATED APPLICATIONS

The present application claims priority of Korean Patent Application No. 10-2011-0017938, filed on Feb. 28, 2011, which is incorporated herein by reference in its entirety.

### BACKGROUND

1. Field

Exemplary embodiments of the present invention relate to an internal voltage generating circuit and testing method of integrated circuit using the same.

2. Description of the Related Art

Most semiconductor devices, including a dynamic random access memory (DRAM), use an external power supply voltage (VDD, VSS, etc.) and internal voltages having different levels from the power supply voltage. In general, the internal voltages are generated using reference voltages for their target levels, an external power supply voltage (VDD), and an external ground voltage (VSS) by a charge pumping method or a voltage down converting method.

For example, the DRMA generates the internal voltages, such as a boosted voltage (VPP), a back bias voltage (VBB), and so on, using the charge pumping method. The internal voltages such as a core voltage (VCORE), a bit line precharge voltage (VBLP), etc are generated using the voltage down converting method.

The boosted voltage (VPP) has a voltage level higher than the external power supply voltage (VDD) and is mainly used to drive a word line. The back bias voltage (VBB) is a negative voltage lower than the ground voltage (VSS) and is mainly used as a body (bulk) bias of a cell transistor (NMOS transistor).

Meanwhile, the core voltage (VCORE) has a voltage level lower than the external power supply voltage (VDD) and corresponding to a logic high level of data stored in a memory cell. The bit line precharge voltage (VBLP) has a voltage level lower than the external power supply voltage (VDD) and is mainly used to equalize bit lines (BL, BLB) in a precharge operation.

FIG. 1 is a block diagram illustrating an internal voltage generating circuit of a conventional semiconductor device.

Referring to FIG. 1, the internal voltage generating circuit of the conventional semiconductor device includes a main reference voltage generating unit 100, a normal reference voltage generating unit 110, a test reference voltage generating unit 120, an operation reference voltage generating unit 130, and an internal voltage generating unit 140.

The main reference voltage generating unit 100 generates a main reference voltage MAIN_VREF maintaining a constant voltage level without regard to process, voltage and temperature (PVT) variations.

The normal reference voltage generating unit 110 receives the main reference voltage MAIN_VREF and generates a normal reference voltage NORMAL_VREF of different voltage levels depending on a type of an internal voltage VINT. For example, in a case in which the internal voltage VINT is a boosted voltage (VPP), the normal reference voltage generating unit 110 generates a boosted normal reference voltage NORMAL_VREFP having a relatively high voltage level. In a case in which the internal voltage VINT is a core voltage (VCORE), the normal reference voltage generating unit 110 generates the normal reference voltage NORMAL_VREF at a relatively low voltage level.

The test reference voltage generating unit 120 generates a test reference voltage TEST_VREF by dividing a voltage level between the external power supply voltage (VDD) and the external ground voltage (VSS) at a set ratio. That is, the level of the test reference voltage TEST_VREF is located at a set point between the levels of the voltages (VDD and VSS) and varies with the variation of the external power supply voltage (VDD).

The operation reference voltage generating unit 130 generates an operation reference voltage ACT_VREF in response to one of the normal reference voltage NORMAL_VREF and the test reference voltage TEST_VREF, which is selected in response to a test signal TM_BI. For example, when the normal reference voltage NORMAL_VREF is selected in response to the test signal TM_BI, the operation reference voltage ACT_VREF has the same level as the normal reference voltage NORMAL_VREF. On the other hand, when the test reference voltage TEST_VREF is selected, the operation reference voltage ACT_VREF has the same level as the test reference voltage TEST_VREF.

Finally, the internal voltage generating unit 140 generates the internal voltage VINT whose level is determined based on the level of the operation reference voltage ACT_VREF. At this time, the detailed configuration and operating method of the internal voltage generating unit 140 may be changed depending on a method of generating the internal voltage VINT, for example, a charge pumping method for generating a boosted voltage (VPP) or a back bias voltage (VBB) and a voltage down converting method for generating a core voltage (VCORE) or a bit line precharge voltage (VBLP).

FIG. 2 is a diagram illustrating features of the internal voltage generating circuit of the conventional semiconductor device illustrated in FIG. 1.

FIG. 2 illustrates an example where the internal voltage VINT is a boosted voltage (VPP). The boosted voltage VPP may include a boosted normal voltage NORMAL_VPP for a normal mode and a boosted test voltage TEST_VPP for a test mode. Other types of internal voltages may be generated by the same method explained in FIG. 2.

Referring to FIG. 2, with the rise of the external power supply voltage VDD, the boosted normal reference voltage NORMAL_VREFP and the boosted normal voltage NORMAL_VPP corresponding to the boosted normal reference voltage NORMAL_VREFP rise. In addition, the level of the boosted test reference voltage TEST_VREFP and the level of the boosted test voltage TEST_VPP corresponding to the boosted test reference voltage TEST_VREFP also rise.

While the boosted normal reference voltage NORMAL_VREFP and the boosted normal voltage NORMAL_VPP are maintained at the same level as the level of the external power supply voltage VDD, they have a constant voltage level without regard to the rise of the external power supply voltage VDD after the power-up signal PWRUP is activated. However, the voltage levels of the boosted test reference voltage TEST_VREFP and the boosted test voltage TEST_VPP continuously keep rising with the rise of the external power supply voltage VDD.

According to a rise in the level of the external power supply voltage VDD, the levels of the boosted test reference voltage TEST_VREFP and the boosted test signal TEST_VPP are made to rise in order to detect errors, which may be caused during the actual operation of the semiconductor device, in advance by making the level of the boosted test voltage TEST_VPP to be higher than the set level of the boosted normal voltage NORMAL_VPP used during the actual operation of the semiconductor device. That is, weak circuits and cells of the semiconductor device may cause errors during the use of the semiconductor device. Such errors can be detected in advance by checking the operation of the week circuits and cells in the harsh conditions.

The method of testing the semiconductor device in harsh operating environment may be classified into an early fail rate (EFR) test method and a test during burn in (TDBI) test method.

The EFR test method detects circuits and cells, which may cause errors at the early stage of the operation , by raising the level of the internal voltage including a bias voltage in the early stage of the test operation.

The TDBI test method detects circuits and cells, which may cause errors, by operating the semiconductor device after supplying it with the internal voltage, which includes a bias voltage and is relatively high as compared to the EFR test method, for a predetermined time.

To perform such a test operation, the boosted test voltage TEST_VPP is made to have a higher level than the boosted normal voltage NORMAL_VPP by continuously raising the levels of the boosted test voltage TEST_VPP and the boosted test reference voltage TEST_VREFP with the rise of the level of the external power supply voltage. As illustrated in FIG. 2, the boosted test voltage TEST_VPP is used in the EFR test method until the boosted test voltage TEST_VPP becomes a predetermined level from the point of time when it becomes higher than the boosted normal voltage NORMAL_VPP. The boosted test voltage TEST_VPP having a higher level than the predetermined level is used in the TDBI test method.

However, as the level of the external power supply voltage VDD rises, the slew rate variation width of the boosted test voltage TEST_VPP becomes large. Because, the boosted test voltage TEST_VPP is generated by charge pumping the level of the boosted test reference voltage TEST_VREFP rising in proportion to the external power supply voltage VDD.

That is, since the boosted test voltage TEST_VPP has a larger slew rate variation width than the external power supply voltage VDD, the level of the boosted test voltage TEST_VPP is considerably changed even though the level of the external power supply voltage VDD is slightly changed. Therefore, in the EFR test method, the boosted test voltage TEST_VPP rapidly may rise to a high level and excessive stress may be applied to the semiconductor device, significantly degrading the reliability of the test result. In the TDBI test method, since the boosted test voltage TEST_VPP rapidly drops to a low level, a screen ability problem may occur so that the semiconductor device may not be properly tested in harsh environment for a sufficiently long time.

### SUMMARY

An embodiment of the present invention is directed to a semiconductor device which is capable of stabilizing a slew rate variation of an internal voltage for a test operation.

In accordance with an embodiment of the present invention, an internal voltage generating circuit includes: a normal reference voltage generating unit configured to generate a normal reference voltage having a constant voltage level without regard to process, voltage and temperature (PVT) variations; a test reference voltage generating unit configured to generate a test reference voltage by dividing a voltage level between an external power supply voltage and the normal reference voltage at a set ratio; and an internal voltage generating unit configured to generate an internal voltage in response to the test reference voltage.

In accordance with another embodiment of the present invention, a testing method of an integrated circuit includes: generating a normal reference voltage having a constant voltage level without regard to PVT variations; generating a test reference voltage having an initial level of the normal reference voltage as an initial value and varying by a level variation width obtained by dividing a level variation width of an external power supply voltage at a set ratio; generating a boosted test voltage by performing a charge pumping operation based on a level of the test reference voltage; performing an early fail rate (EFR) test operation using the boosted test voltage; and performing a test during burn in (TDBI) test operation using the boosted test voltage.

In accordance with still another embodiment of the present invention, an internal voltage generating circuit includes: a main reference voltage generating unit configured to generate a main reference voltage; a sub reference voltage generating unit configured to generate a first sub reference voltage by dividing the main reference voltage at a first set ratio and generate a second sub reference voltage by dividing the main reference voltage at a second set ratio; a test reference voltage generating unit configured to generate a first test reference and a second test reference voltage in response to the first sub reference voltage and the second sub reference voltage, respectively; an operation reference voltage generating unit configured to generate a first operation reference voltage in response to one of the first sub reference voltage and the first test reference voltage, and generate a second operation reference voltage in response to one of the second sub reference voltage and the second test reference voltage; a first internal voltage generating unit configured to generate a first internal voltage based on a level of the first operation reference voltage; and a second internal voltage generating unit configured to generate a second initial voltage based on a level of the second operation reference voltage.

### BRIEF DESCRIPTION OF THE DRAWINGS

FIG. 1 is a block diagram illustrating an internal voltage generating circuit of a conventional semiconductor device.

FIG. 2 is a diagram illustrating features of the internal voltage generating circuit of the conventional semiconductor device illustrated in FIG. 1.

FIG. 3A is a block diagram illustrating a boosted test voltage generating circuit of a semiconductor device in accordance with a first embodiment of the present invention.

FIG. 3B is a block diagram illustrating an internal voltage generating circuit of the semiconductor device in accordance with the first embodiment of the present invention.

FIG. 4 is a diagram illustrating the operation of the internal voltage generating circuit illustrated in FIG. 3B in accordance with the first embodiment of the present invention.

FIGS. 5A and 5B are circuit diagrams illustrating a normal reference voltage generating unit shown in FIGS. 3A and 3B in accordance with the first embodiment of the present invention.

FIG. 5C is a circuit diagram illustrating a test voltage generating unit shown in FIGS. 3A and 3B and an operation reference voltage outputting unit shown in FIG. 3B in accordance with the first embodiment of the present invention.

FIG. 5D is a block diagram illustrating a boosted test voltage generating unit shown in FIG. 3A and an internal voltage generating unit using a charge pumping method shown in FIG. 3B.

FIG. 5E is a block diagram illustrating an internal voltage generating unit using a voltage down converting method shown in FIG. 3B.

FIG. 6 is a block diagram illustrating an internal voltage generating circuit of the semiconductor device in accordance with the second embodiment of the present invention.

FIG. 7 illustrates generally an embodiment of a computer system according to an aspect of the present invention.

FIG. 8 illustrates is a block diagram showing an example of a motherboard shown in FIG. 7.

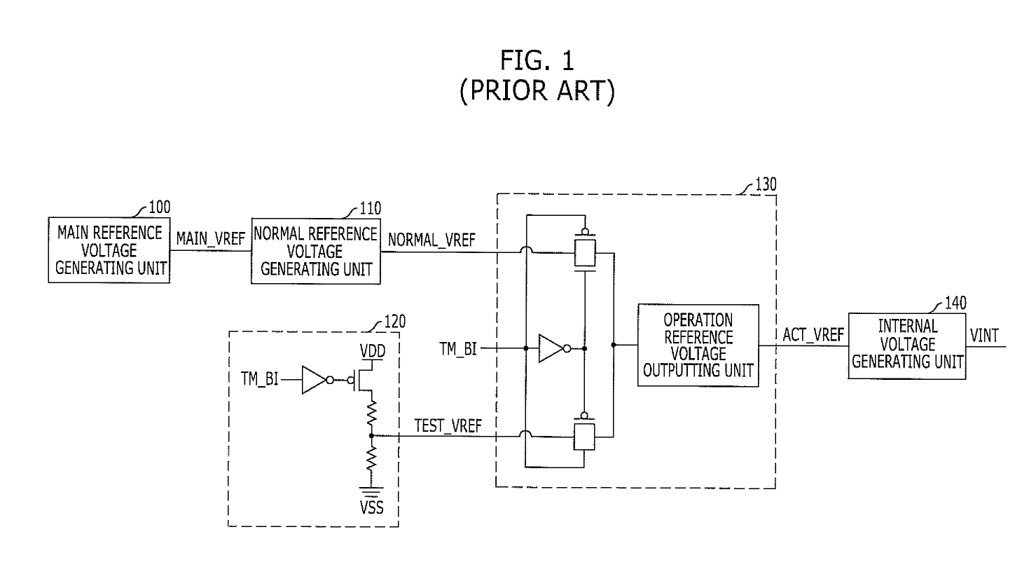

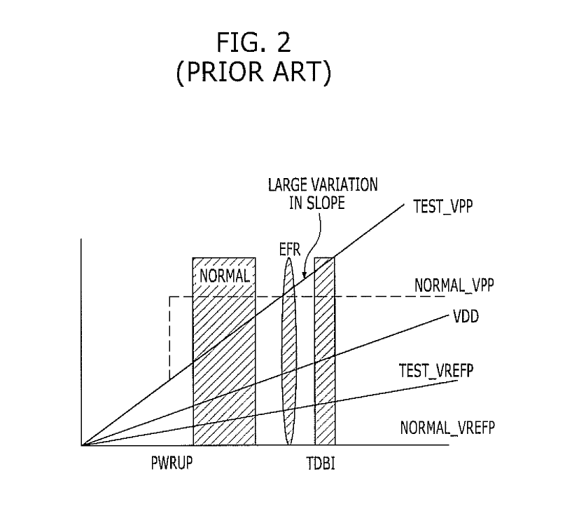

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

### First Embodiment

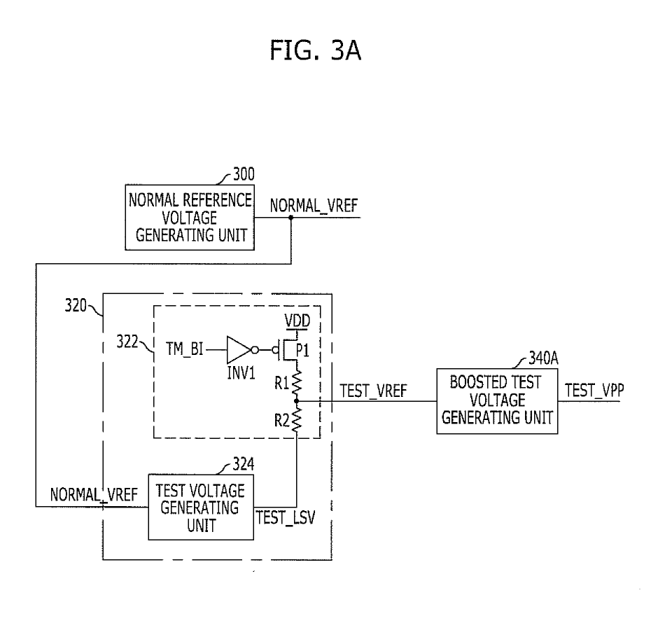

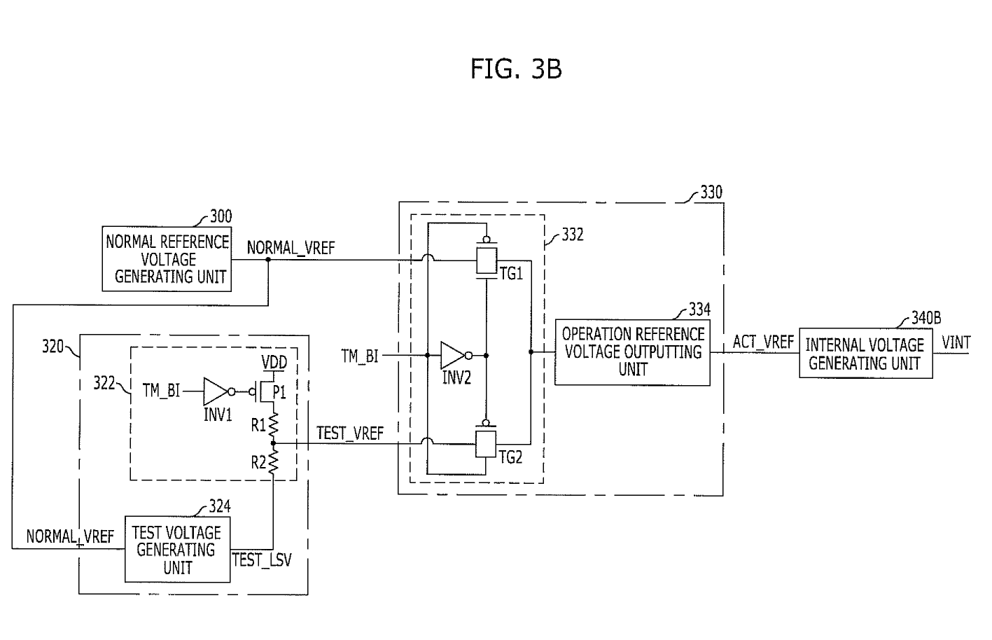

FIG. 3A is a block diagram illustrating a boosted test voltage generating circuit of a semiconductor device in accordance with a first embodiment of the present invention.

Referring to FIG. 3A, the boosted test voltage generating circuit of the semiconductor device in accordance with the first embodiment of the present invention includes a normal reference voltage generating unit 300, a test reference voltage generating unit 320, and a boosted test voltage generating unit 340A.

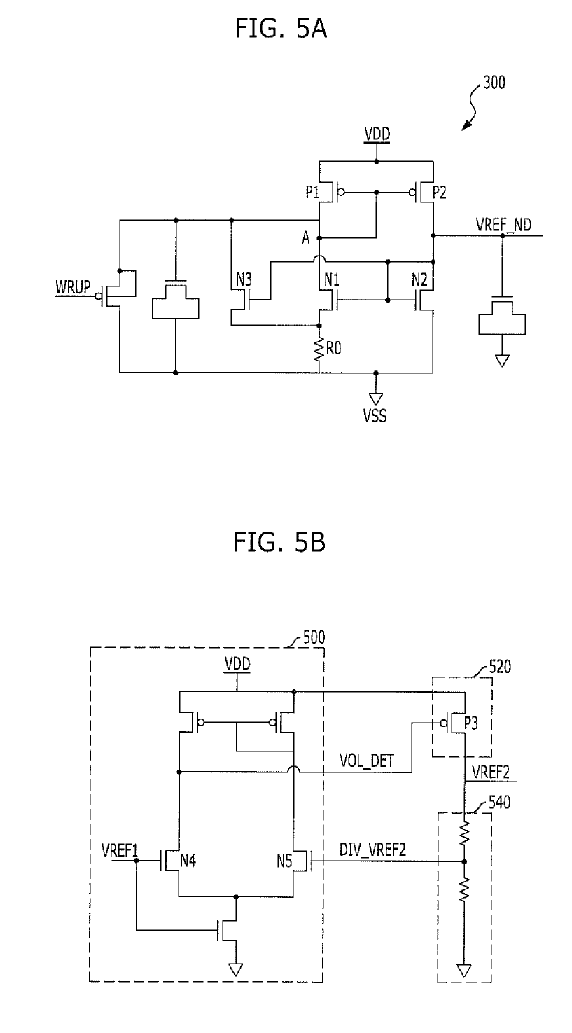

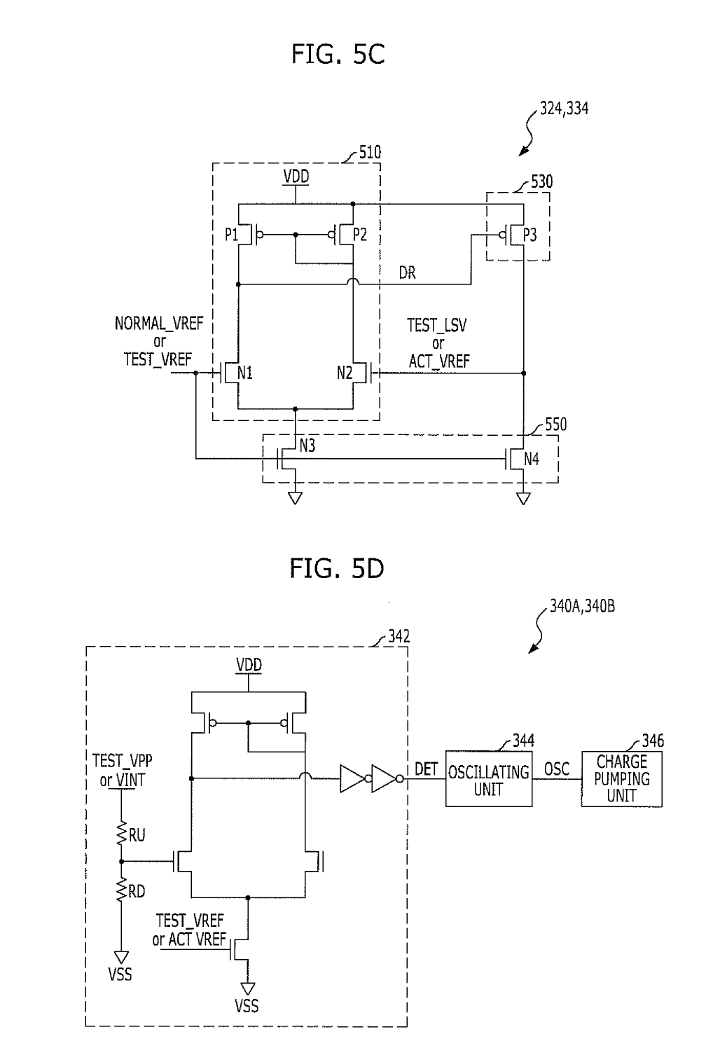

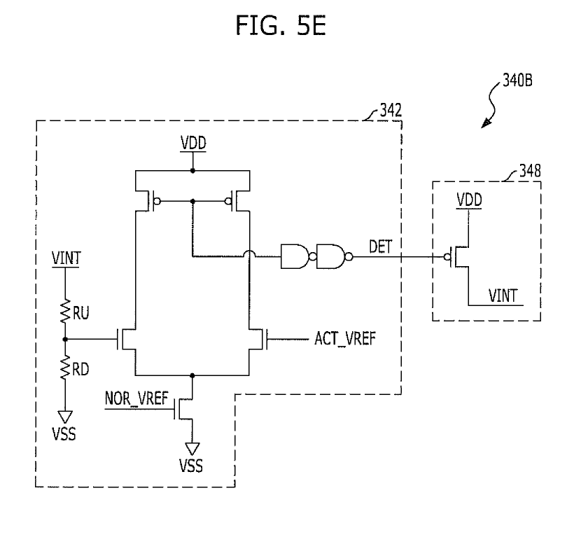

The normal reference voltage generating unit 300 generates a normal reference voltage NORMAL_VREF having a constant voltage level without regard to PVT variations. The configuration of the normal reference voltage generating unit 300 is described as follows with reference to FIGS. 5A and 5B.

First, the normal reference voltage generating unit 300 may include a Widlar type reference voltage generating circuit illustrated in FIG. 5A.

Referring to FIG. 5A, the Widlar type reference voltage generating circuit includes a resistor and transistors. A first PMOS transistor P1 has a source connected to an external power supply voltage terminal VDD and a drain connected to a node A. A second PMOS transistor P2 has a gate commonly connected to a gate of the first PMOS transistor P1 and a source connected to the external power supply voltage terminal VDD. A second NMOS transistor N2 has a gate and a drain commonly connected to a drain of the second PMOS transistor P2 and a source connected to a ground voltage terminal VSS. A first NMOS transistor N1 has a gate commonly connected to the gate of the second NMOS transistor N2 and a drain commonly connected to the drain of the first PMOS transistor P1. A resistor R0 is connected between a source of the first NMOS transistor N1 and the ground voltage terminal VSS. A third NMOS transistor N3 has a gate commonly connected to the gate of the first NMOS transistor N1, a source connected between the first NMOS transistor N1 and the resistor R0, and a drain connected to the gates of the first and second PMOS transistors P1 and P2.

Upon operation, when the external power supply voltage VDD is applied, the second PMOS transistor P2 operates as a diode. Thus, a reference voltage output node VREF_ND outputs a voltage lower than the external power supply voltage VDD by the threshold voltage (Vt) of the second PMOS transistor P2. Since the potential of the reference voltage output node VREF_ND is connected to the gate of the first NMOS transistor N1, the on/off operation of the first NMOS transistor N1 is controlled by the potential of the reference voltage output node VREF_ND and a constant current is transferred to the node A. Since the second NMOS transistor N2 is diode-connected, the reference voltage output node VREF_ND connected to the drain of the second PMOS transistor P2 is clamped at a voltage level higher than the threshold voltage (Vt) of the second NMOS transistor N2.

The reference voltage output node VREF_ND is also connected to the gate of the second NMOS transistor N2 to thereby form a large resistance, and the first NMOS transistor N1 is connected to the resistor R0 to perform temperature compensation operation.

That is, in the case of a conductor, the amount of current is inversely proportional to the height of temperature. In the case of a semiconductor, the amount of current is proportional to the height of temperature. Thus, by combining a conductor and a semiconductor, a constant current may flow at a certain point regardless of temperature. This point is called a zero temperature coefficient. The first NMOS transistor N1 is a semiconductor (nonconductor) when it is not turned on, and the first NMOS transistor N1 is a conductor when it is turned on. Therefore, the first NMOS transistor N1 can achieve a temperature compensation effect through the connection to the active resistor R0 which is a conductor.

In addition, the normal reference voltage generating unit 300 may include the structure combining the Widlar type reference voltage generating circuit of FIG. 5A and the level shifter of FIG. 5B.

Specifically, referring to FIG. 5B, the normal reference voltage generating unit 300 includes a differential amplifying unit 500, a driving unit 520, and a voltage dividing unit 540. The differential amplifying unit 500 amplifies a difference between a first reference voltage VREF1 outputted from the Widlar type reference voltage generating circuit of FIG. 5A and a second reference voltage VREF2 outputted from the level shifter. The differential amplifying unit 500 acts as a voltage follower.

The differential amplifying unit 500 compares the first reference voltage VREF1 having a constant voltage level with respect to the external power supply voltage VDD with an output voltage DIV_VREF2 of the voltage dividing unit 540 and generates a voltage comparison signal VOL_DET based on the comparison result. The driving unit 520 generates the second reference voltage VREF2 in response to the voltage comparison signal VOL_DET outputted from the differential amplifying unit 500. In addition, the voltage dividing unit 540 generates the output voltage DIV_VREF2 by dividing the level of the second reference voltage VREF2 at a set ratio. In this case, the set ratio is changed depending on a target level of the second reference voltage VREF2.

Upon operation, the output voltage DIV_VREF2 of the voltage dividing unit 540 is controlled to have the same voltage level as the first reference voltage VREF1. Therefore, when the output voltage DIV_VREF2 of the voltage dividing unit 540 is lower than the first reference voltage VREF1, the voltage level of the voltage comparison signal VOL_DET outputted from the differential amplifying unit 500 is lowered to turn on a PMOS transistor P3 constituting the driving unit 520. Since the external power supply voltage VDD is supplied to the second reference voltage (VREF2) terminal, the voltage level of the second reference voltage (VREF2) terminal rises and the level of the output voltage DIV_VREF2 of the voltage dividing unit 540 also rises. When the output voltage (DIV_VREF2) level of the voltage dividing unit 540 becomes equal to the level of the first reference voltage VREF1, the differential amplifying unit 500 stops outputting the lowered voltage comparison signal VOL_DET.

Since transistors N4 and N5 included in the differential amplifying unit 500 operate in a saturation region, the differential amplifying unit 500 performs a proper operation. That is, in a case in which the level of the output voltage DIV_VREF2 of the voltage dividing unit 540 drops, undershoot, or overshoot due to a load connected to the second reference voltage (VREF2) terminal, the differential amplifying unit 500 restores the output voltage (DIV_VREF2) level of the voltage dividing unit 540 to the same voltage level as the first reference voltage VREF1 so that the level of the second reference voltage (VREF2) terminal can become equal to the target level.

The test reference voltage generating unit 320 generates a test reference voltage TEST_VREF by dividing a voltage level between the external power supply voltage VDD and the normal reference voltage NORMAL_VREF at a set ratio. That is, the level of the test reference voltage TEST_VREF is changed with the change of the level of the external power supply voltage VDD, while it is higher than the level of the normal reference voltage NORMAL_VREF.

The configuration of the test reference voltage generating unit 320 is described as follows. The test reference voltage generating unit 320 includes a test voltage generating unit 324 and a voltage dividing unit 322. The test voltage generating unit 324 receives the normal reference voltage NORMAL_VREF and generates a test voltage TEST_LSV having the same level as the normal reference voltage NORMAL_VREF. The voltage dividing unit 322 determines the level of the test reference voltage TEST_VREF by dividing a voltage level between the external power supply voltage VDD and the test voltage TEST_LSV at a set ratio. The operation of the voltage dividing unit 322 is controlled in response to a test signal TM_BI.

The test voltage generating unit 324 may be a unit gain buffer (UGB) which outputs the test voltage TEST_LSV having the same voltage level as the inputted normal reference voltage NORMAL_VREF.

The configuration of the test voltage generating unit 324 is described as follows with reference to FIG. 5C. The test voltage generating unit 324 includes a voltage level comparing unit 510, a driving unit 530, and a sinking current driving unit 550. The voltage level comparing unit 510 compares the level of the input voltage NORMAL_VREF with the output voltage TEST_LSV. The driving unit 530 drives a terminal of the output voltage TEST_LSV with the external power supply voltage VDD in response to an output signal DR of the voltage level comparing unit 510. The sinking current driving unit 550 controls the same amount of current to sink from the voltage level comparing unit 510 and the output voltage (TEST_LSV) terminal in response to the input voltage NORMAL_VREF.

Upon operation, the voltage level comparing unit 510 regulates the driving force of the driving unit 530 so that the input voltage NORMAL_VREF and the output voltage TEST_LSV have the same voltage level. At this time, since the sinking current driving unit 550 performs a control so that the same amount of current sinks from the voltage level comparing unit 510 and the output voltage (TEST_LSV) terminal, the level of the input voltage NORMAL_VREF and the level of the output voltage TEST_LSV can be always in the same state.

The voltage dividing unit 322 includes a switch P1, a first resistor R1, and a second resistor R2, which are coupled in series between the external power supply voltage (VDD) terminal and the test voltage (TEST_LSV) terminal. The switch P1 is turned on/off in response to the test signal TM_BI, and the test reference voltage TEST_VREF is outputted at a connection node of the first resistor R1 and the second resistor R2. Although a PMOS transistor is illustrated as the switch P1 in FIG. 3, this is an exemplary embodiment and may be changed depending on different design needs. In addition, although FIG. 3 illustrates that the test signal TM_BI is inverted by an inverter INV1 and the on/off operation of the PMOS transistor is controlled by the inverted test signal, this may be also changed depending on different design needs.

The boosted test voltage generating unit 340A generates a boosted test voltage TEST_VPP whose level is determined based on the level of the test reference voltage TEST_VREF. Since the boosted test voltage TEST_VPP is a voltage generated using a charge pumping method, the boosted test voltage generating unit 340 may be configured as illustrated in FIG. 5D.

Specifically, referring to FIG. 5D, the boosted test voltage generating unit 340A includes a voltage level detecting unit 342, an oscillating unit 344, and a charge pumping unit 346. The voltage level detecting unit 342 detects the level of the boosted test voltage TEST_VPP based on the level of the test reference voltage TEST_VREF. The oscillating unit 344 generates an oscillation signal OSC toggling at a set frequency, and the on/off operation of the oscillating unit 344 is controlled in response to an output signal DET of the voltage level detecting unit 342. The charging pumping unit 346 varies a level of the boosted test voltage TEST_VPP by performing a charge pumping operation in response to the toggling of the oscillation signal OSC.

FIG. 3B is a block diagram illustrating an internal voltage generating circuit of the semiconductor device in accordance with the first embodiment of the present invention.

Referring to FIG. 3B, the internal voltage generating circuit of the semiconductor device in accordance with the first embodiment of the present invention includes a normal reference voltage generating unit 300, a test reference voltage generating unit 320, an operation reference voltage generating unit 330, and an internal voltage generating unit 340B.

Since the configurations of the normal reference voltage generating unit 300 and the test reference voltage generating unit 320 are substantially identical to those of FIG. 3A, the following description will be focused on the operation reference voltage generating unit 330 and the internal voltage generating unit 340B.

The operation reference voltage generating unit 330 generates an operation reference voltage ACT_VREF in response to one of the normal reference voltage NORMAL_VREF and the test reference voltage TEST_VREF which is selected in response to the test signal TM_BI. For example, when the normal reference voltage NORMAL_VREF is selected in response to the test signal TM_BI, the operation reference voltage ACT_VREF has the same level as the normal reference voltage NORMAL_VREF. On the other hand, when the test reference voltage TEST_VREF is selected, the operation reference voltage ACT_VREF has the same level as the test reference voltage TEST_VREF.

More specifically, the operation reference voltage generating unit 330 includes a voltage selection outputting unit 332 and an operation reference voltage outputting unit 334. The voltage selection outputting unit 332 receives the normal reference voltage NORMAL_VREF and the test reference voltage TEST_VREF, outputs the normal reference voltage NORMAL_VREF in a deactivated period of the test signal TM_BI, and outputs the test reference voltage TEST_VREF in an activated period of the test signal TM_BI. The operation reference voltage outputting unit 334 generates the operation reference voltage ACT_VREF having the same level as the output voltage of the voltage selection outputting unit 332.

The operation reference voltage outputting unit 334 may be a unit gain buffer (UGB) which outputs the operation reference voltage ACT_VREF having the same level as the output voltage of the voltage selection outputting unit 332.

That is, the operation reference voltage outputting unit 334 may be the unit gain buffer of the same type as the test voltage generating unit 324 described above with reference to FIG. 3A. More specifically, referring to FIG. 5C, the operation reference voltage generating unit 334 includes a voltage level comparing unit 510, a driving unit 530, and a sinking current driving unit 550. The voltage level comparing unit 510 compares the level of the input voltage NORMAL_VREF or TEST_VREF with the output voltage ACT_VREF. The driving unit 530 drives a terminal of the output voltage ACT_VREF with the external power supply voltage VDD in response to an output signal DR of the voltage level comparing unit 510. The sinking current driving unit 550 controls the same amount of current sink from the voltage level comparing unit 510 and the output voltage (ACT_VREF) terminal in response to the input voltage NORMAL_VREF or TEST_VREF.

Upon operation, the voltage level comparing unit 510 regulates the driving force of the driving unit 530 so that the input voltage NORMAL_VREF or TEST_VREF and the output voltage ACT_VREF have the same voltage level. At this time, since the sinking current driving unit 550 performs a control so that the same amount of current sink from the voltage level comparing unit 510 and the output voltage (ACT_VREF) terminal, the level of the input voltage NORMAL_VREF or TEST_VREF and the level of the output voltage ACT_VREF can be always in the same state.

The internal voltage generating unit 340B generates an internal voltage VINT whose level is determined based on the level of the operation reference voltage ACT_VREF. The detailed configuration and operating method of the internal voltage generating unit 340B may be changed depending on a type of the internal voltage VINT, for example, a boosted voltage (VPP) or a back bias voltage (VBB) generated using a charge pumping method and a core voltage (VCORE) or a bit line precharge voltage (VBLP) generated using a voltage down converting method.

In a case in which the internal voltage generating unit 340B generates the internal voltage VINT using the charge pumping method, such as a boosted voltage (VPP) or a back bias voltage (VBB), the internal voltage generating unit 340B may be configured as illustrated in FIG. 5D. Specifically, referring to FIG. 5D, the internal voltage generating unit 340B includes a voltage level detecting unit 342, an oscillating unit 344, and a charge pumping unit 346. The voltage level detecting unit 342 detects the level of the internal voltage VINT based on the level of the operation reference voltage ACT_VREF. The oscillating unit 344 generates an oscillation signal OSC toggling at a set frequency, and the on/off operation of the oscillating unit 344 is controlled in response to an output signal DET of the voltage level detecting unit 342. The charging pumping unit 346 varies the level of the internal voltage VINT by performing a charge pumping operation in response to the toggling of the oscillation signal OSC.

On the other hand, in a case in which the internal voltage generating unit 340B generates the internal voltage VINT using the voltage down converting method, such as a core voltage (VCORE) or a bit line precharge voltage (VBLP), the internal voltage generating unit 340B may be configured as illustrated in FIG. 5E. Specifically, referring to FIG. 5E the internal voltage generating unit 340B includes a voltage level detecting unit 342 and a voltage down converting unit 348. The voltage level detecting unit 342 detects the level of the internal voltage VINT based on the level of the operation reference voltage ACT_VREF. The voltage down converting unit 348 receives the external power supply voltage VDD and varies the level of the internal voltage VINT by driving the internal voltage (VINT) terminal, and the driving force of the voltage down converting unit 348 is regulated in response to the output signal of the voltage level detecting unit 342.

The operation of the internal voltage generating circuit of the semiconductor device in accordance with the first embodiment of the present invention is described as follows with reference to the above-described configuration thereof.

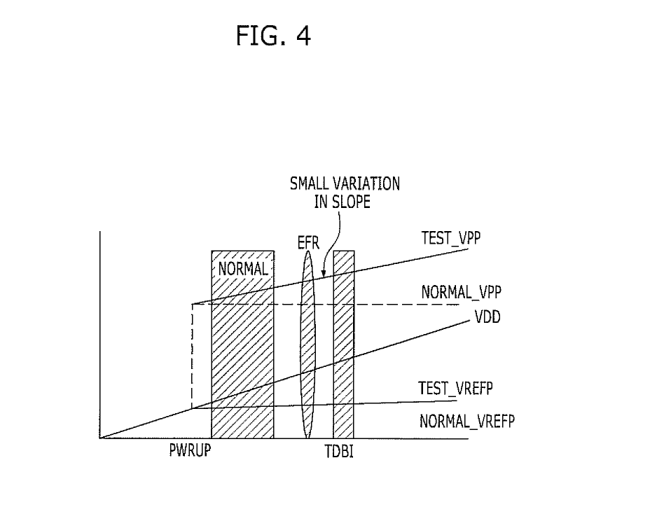

FIG. 4 is a diagram illustrating the operation of the internal voltage generating circuit illustrated in FIG. 3B in accordance with the first embodiment of the present invention.

FIG. 4 illustrates an example that the internal voltage VINT is the boosted voltage (VPP), and other types of internal voltages, including all internal voltages used in the semiconductor device, such as a back bias voltage (VBB), a core voltage (VCORE), or a bit line precharge voltage (VBLP), can also be applied to the operation described as follows with reference to FIG. 4.

Referring to FIG. 4, with the rise of the external power supply voltage VDD, the boosted normal reference voltage NORMAL_VREFP and the boosted normal voltage NORMAL_VPP corresponding to the boosted normal reference voltage NORMAL_VREFP rise. In addition, the level of the boosted test reference voltage TEST_VREFP and the level of the boosted test voltage TEST_VPP corresponding to the boosted test reference voltage TEST_VREFP also rise.

While the boosted normal reference voltage NORMAL_VREFP and the boosted normal voltage NORMAL_VPP maintain the same level as the level of the external power supply voltage VDD, they have a constant voltage level without regard to the rise of the external power supply voltage VDD after the logic level transition of the power-up signal PWRUP.

The boosted test reference voltage TEST_VREFP and the boosted test voltage TEST_VPP maintain the same level as the external power supply voltage VDD before the logic level transition of the power-up signal PWRUP, just like the boosted normal reference voltage NORMAL_VREFP and the boosted normal voltage NORMAL_VPP. After the logic level transition, the boosted test reference voltage TEST_VREFP and the boosted test voltage TEST_VPP rise in proportion to the external power supply voltage VDD. For example, the boosted test reference voltage TEST_VREFP and the boosted test voltage TEST_VPP may rise by a set raise which is obtained by dividing the raise of the external power supply voltage VDD at a set ratio.

That is, the levels of the boosted test reference voltage TEST_VREFP and the boosted test voltage TEST_VPP vary with the variation in the level of the external power supply voltage VDD, and the level variation width thereof may become much smaller than the level variation width of the external power supply voltage VDD after the power-up signal PWRUP is activated.

The boosted test reference voltage TEST_VREFP and the boosted test voltage TEST_VPP can have the voltage level characteristics illustrated in FIG. 4 because the boosted test reference voltage TEST_VREFP is generated by dividing the voltage level between the external power supply voltage VDD and the boosted normal reference voltage NORMAL_VREFP. That is, the level of the boosted test reference voltage TEST_VREFP rises by a raise set smaller than that of the external power supply voltage VDD with the rise of the external power supply voltage VDD from the point of time when the boosted normal reference voltage NORMAL_VREFP and the external power supply voltage VDD have different voltage levels.

Therefore, the slew rate variation width of the boosted test reference voltage TEST_VREFP becomes very smaller than the slew rate variation width of the external power supply voltage VDD. Thus, the slew rate variation width of the boosted test voltage TEST_VPP may become smaller than the slew rate variation width of the external power supply voltage VDD.

Since the boosted test voltage TEST_VPP has the smaller slew rate variation width than the external power supply voltage VDD, slight variation in the level of the external power supply voltage VDD due to noise does not greatly influence the level of the boosted test voltage TEST_VPP. That is, the level of the boosted test voltage TEST_VPP can be varied very stably with the variation in the level of the external power supply voltage VDD. Therefore, the boosted test voltage TEST_VPP may be prevented from rapidly rising to a very high level or rapidly dropping to a very low level when the test is performed using the EFR test method and the TDBI test method.

When the internal voltage generating method in accordance with the first embodiment of the present invention is applied to the semiconductor device, the test operation can be performed very stably, thereby preventing the waste of resources (cost, time, etc.) consumed in the test operation.

### Second Embodiment

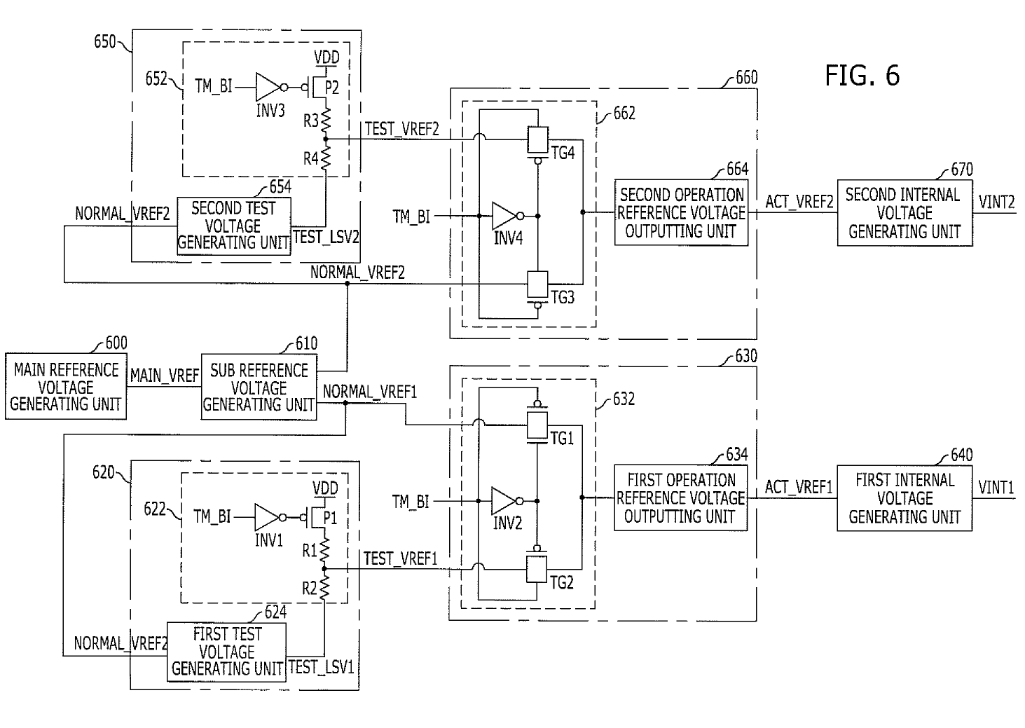

FIG. 6 is a block diagram illustrating an internal voltage generating circuit of a semiconductor device in accordance with a second embodiment of the present invention.

Referring to FIG. 6, the internal voltage generating circuit of the semiconductor device in accordance with the second embodiment of the present invention includes a main reference voltage generating unit 600, a sub reference voltage generating unit 610, test reference voltage generating units 620 and 650, operation reference voltage generating units 630 and 660, a first internal voltage generating unit 640, and a second internal voltage generating unit 670.

The main reference voltage generating unit 600 generates a main reference voltage MAIN_VREF having a constant voltage level without regard to PVT variations. Since the main reference voltage generating unit 600 has the same configuration as that described above in the first embodiment with reference to FIG. 5A, a description thereof is omitted.

The sub reference voltage generating unit 610 generates a first sub reference voltage NORMAL_VREF1 by dividing the main reference voltage MAIN_VREF at a first ratio and generates a second sub reference voltage NORMAL_VREF2 by dividing the main reference voltage MAIN_VREF at a second ratio. The sub reference voltage generating unit 610 may have the same configuration as that described above in the first embodiment with reference to FIG. 5B. That is, a number of the level shifter of FIG. 5B may be provided in the sub reference voltage generating unit 610 to equal the number of the sub reference voltages (NORMAL_VREF1 and NORMAL_VREF2) to be outputted.

The test reference voltage generating units 620 and 650 generate a first test reference voltage TEST_VREF1 by dividing a voltage level between the external power supply voltage VDD and the first sub reference voltage NORMAL_VREF1 at a first test ratio and generates a second test reference voltage TEST_VREF2 by dividing a voltage level between the external power supply voltage VDD and the second sub reference voltage NORMAL_VREF2 at a second test ratio.

The configuration of the test reference voltage generating units 620 and 650 is described as follows. The test reference voltage generating units 620 and 650 include test voltage generating units 624 and 654 and voltage dividing units 622 and 652, respectively. The first test voltage generating unit 624 receives the first sub reference voltage NORMAL_VREF1 and generates a first test voltage TEST_LSV1 having the same level as the first sub reference voltage NORMAL_VREF1, and the second test voltage generating unit 654 receives the second sub reference voltage NORMAL_VREF2 and generates the second test voltage TEST_LSV2 having the same level as the second sub reference voltage NORMAL_VREF2. The voltage dividing unit 622 determines the level of the first test reference voltage TEST_VREF1 by dividing the voltage level between the external power supply voltage VDD and the first test voltage TEST_LSV1 at the first test ratio, and the voltage dividing unit 652 determines the level of the second test reference voltage TEST_VREF2 by dividing the voltage level between the external power supply voltage VDD and the second test voltage TEST_LSV2 at the second test ratio. The operation of the voltage dividing units 622 and 652 is controlled in response to a test signal TM_BI.

The first test voltage generating unit 624 includes a unit gain buffer (UGB) which outputs the first test voltage TEST_LSV1 having the same voltage level as the first sub reference voltage NORMAL_VREF1, and the second test voltage generating unit 654 includes a unit gain buffer (UGB) which outputs the second test voltage TEST_LSV2 having the same voltage level as the second sub reference voltage NORMAL_VREF2. Since the detailed description of the unit gain buffer (UGB) is described above in the first embodiment with reference to FIG. 5C, a further detailed description thereof is omitted.

In addition, the first voltage dividing unit 622 includes a first switch P1, a first resistor R1, and a second resistor R2 which are coupled in series between the external power supply voltage (VDD) terminal and the first test voltage (TEST_LSV1) terminal. The on/off operation of the first switch P1 is controlled in response to the test signal TM_BI, and the first test reference voltage TEST_VREF1 is outputted at a connection node of the first resistor R1 and the second resistor R2. The second voltage dividing unit 652 includes a second switch P2, a third resistor R3, and a fourth resistor R4 which are coupled in series between the external power supply voltage (VDD) terminal and the second test voltage (TEST_LSV2) terminal. The on/off operation of the second switch P2 is controlled in response to the test signal TM_BI, and the second test reference voltage TEST_VREF2 is outputted at a connection node of the third resistor R3 and the fourth resistor R4. Although PMOS transistors are illustrated as the first switch P1 and the second switch P2 in FIG. 6, this is an exemplary embodiment and may be changed depending on different design needs. In addition, although FIG. 6 illustrates that the test signal TM_BI is inverted by inverters INV1 and INV3 and the on/off operation of the PMOS transistors is controlled by the inverted test signal, this may be also changed depending on different design needs.

The operation reference voltage generating unit 630 generates a first operation reference voltage ACT_VREF1 in response to one of the first sub reference voltage NORMAL_VREF1 and the first test reference voltage TEST_VREF1, which is selected in response to the test signal TM_BI, and the operation reference voltage generating unit 660 generates a second operation reference voltage ACT_VREF2 in response to one of the second sub reference voltage NORMAL_VREF2 and the second test reference voltage TEST_VREF2, which is selected in response to the test signal TM_BI. For example, when the first sub reference voltage NORMAL_VREF1 and the second sub reference voltage NORMAL_VREF2 are selected in response to the test signal TM_BI, the first operation reference voltage ACT_VREF1 and the second operation reference voltage ACT_VREF2 have the same level as the first sub reference voltage NORMAL_VREF1 and the second sub reference voltage NORMAL_VREF2, respectively. On the other hand, when the first test reference voltage TEST_VREF1 and the second test reference voltage TEST_VREF2 are selected, the first operation reference voltage ACT_VREF1 and the second operation reference voltage ACT_VREF2 have the same level as the first test reference voltage TEST_VREF1 and the second test reference voltage TEST_VREF2, respectively.

More specifically, the operation reference voltage generating unit 630 includes a first voltage selection outputting unit 632 and a first operation reference voltage outputting unit 634. The first voltage selection outputting unit 632 receives the first sub reference voltage NORMAL_VREF1 and the first test reference voltage TEST_VREF1, outputs the first sub reference voltage NORMAL_VREF1 in a deactivated period of the test signal TM_BI, and outputs the first test reference voltage TEST_VREF1 in an activated period of the test signal TM_BI. The first operation reference voltage outputting unit 634 generates the first operation reference voltage ACT_VREF1 having the same level as the output voltage of the first voltage selection outputting unit 632. The second voltage selection outputting unit 662 receives the second sub reference voltage NORMAL_VREF2 and the second test reference voltage TEST_VREF2, outputs the second sub reference voltage NORMAL_VREF2 in the deactivated period of the test signal TM_BI, and outputs the second test reference voltage TEST_VREF2 in the activated period of the test signal TM_BI. The second operation reference voltage outputting unit 664 generates the second operation reference voltage ACT_VREF2 having the same level as the output voltage of the second voltage selection outputting unit 662.

The first operation reference voltage outputting unit 634 and the second operation reference voltage outputting unit 664 may be unit gain buffers (UGB) which output the first operation reference voltage ACT_VREF1 and the second operation reference voltage ACT_VREF2 having the same voltage level as the output voltages of the first voltage selection outputting unit 632 and the second voltage selection outputting unit 662, respectively. Since the unit gain buffers are described above in the first embodiment with reference to FIG. 5C, a further detailed description thereof is omitted.

The first internal voltage generating unit 640 generates a first internal voltage VINT1 by performing a charge pumping operation based on the level of the first operation reference voltage ACT_VREF1. Since the detailed configuration of the circuit performing the charge pumping operation is described above in the first embodiment with reference to FIG. 5D, a further detailed description thereof is omitted.

The second internal voltage generating unit 670 generates a second internal voltage VINT2 by performing a voltage down converting operation based on the level of the second operation reference voltage ACT_VREF2. Since the detailed configuration of the circuit performing the voltage down converting operation is described above in the first embodiment with reference to FIG. 5E, a further detailed description thereof is omitted.

The various voltage generating methods may be applied to the internal voltage generating circuit of the semiconductor device in accordance with the second embodiment of the present invention. That is, even when a plurality of internal voltages VINT1 and VINT2 are generated using different generating methods (including the charge pumping method, the voltage down converting method, and other methods) with respect to a plurality of sub reference voltages NORMAL_VREF1 and NORMAL_VREF2 having different target voltage levels, a plurality of test reference voltages TEST_VREF1 and TEST_VREF2 may be generated by dividing the voltage level between the plurality of sub reference voltages NORMAL_VREF1 and NORMAL_VREF2 and the external power supply voltage VDD at a set ratio in accordance with the present invention. Therefore, the operation waveform of each sub reference voltage NORMAL_VREF1 or NORMAL_VREF2 and the test reference voltage TEST_VREF1 or TEST_VREF2 in accordance with the second embodiment of the present invention is substantially identical to the operation waveform of the sub reference voltage NORMAL_VREF and the test reference voltage TEST_VREF described above in the first embodiment with reference to FIG. 4. Hence, a further description thereof is omitted.

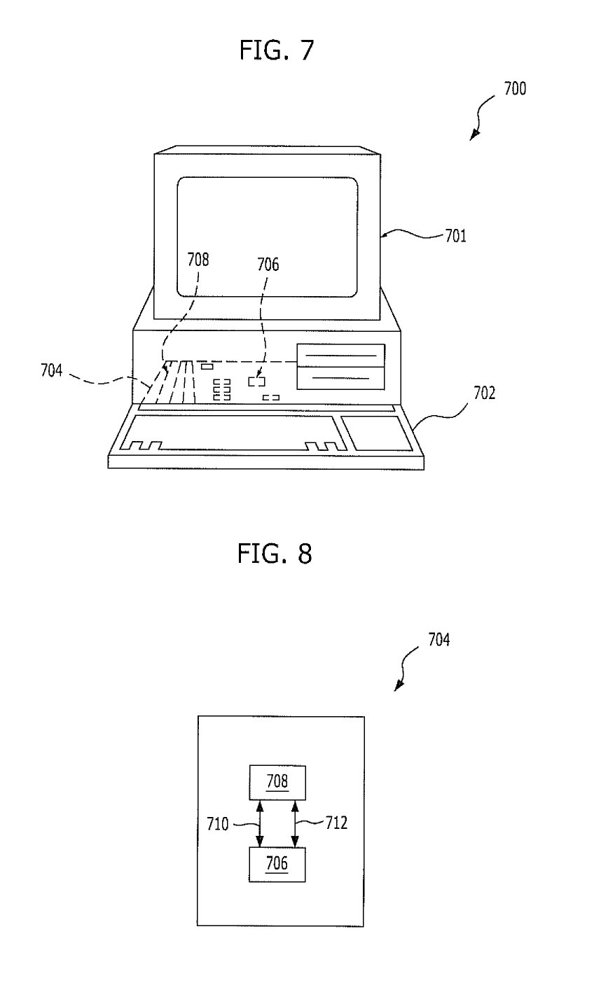

FIG. 7 illustrates an embodiment of a computer system according to an aspect of the present invention, and FIG. 8 illustrates is a block diagram showing an example of a motherboard shown in FIG. 7.

Referring to FIGS. 7 and 8, computer system 700 includes an output device (e.g., monitor) 701, a keyboard (e.g., input device) 702, and a motherboard 704.

The motherboard 704 may carry a data processing unit (e.g., microprocessor) 706 and at least one memory device 708. The memory device 708 may comprise various aspects of the invention described above. The memory device 708 may comprise an array of memory cells, and such array can be coupled with addressing circuitry for accessing individual memory cells in the array. Further, the memory cell array may be coupled to a read circuitry for reading data from the memory cells. The addressing and read circuitry can be utilized for conveying information between the memory device 708 and the processing unit 706. The addressing circuitry is illustrated as 710 of FIG. 8 and the read circuitry is illustrated as 712 of FIG. 8. Various components of the computer system 700 including the processing unit 706 may comprise at least one memory construction described in the present invention.

The processing unit 706 may correspond to a processor module, and associated memory utilized with the module may comprise teachings of the present invention.

The memory device 708 may correspond to a memory module. For example, single in-line memory modules (DIMMs) and dual in-line memory modules (DIMMs) may be used in the implementations which utilize the teachings of the present invention.

In accordance with the exemplary embodiments of the present invention, when the test operation of operating the semiconductor device in harsh operation environment is performed through the EFR test method and the TDBI test method, the voltage level variation period of the internal voltage for test is limited in correspondence to the level variation of the external power supply voltage VDD. Hence, the level of the internal voltage for test can be stably maintained at the target level, even though the level of the external power supply voltage VDD is changed due to noise.

Therefore, the internal voltage for test may be prevented from rapidly rising to a very high level or rapidly dropping to a very low level when the test is performed using the EFR test method and the TDBI test method.

When the internal voltage generating methods in accordance with the embodiments of the present invention are applied to the semiconductor device, the test operation can be performed very stably, thereby preventing the waste of resources (cost, time, etc.) consumed in the test operation.

While the present invention has been described with respect to the specific embodiments, it will be apparent to those skilled in the art that various changes and modifications may be made without departing from the spirit and scope of the invention as defined in the following claims.

For example, the positions and kinds of the logic gates and transistors set forth above may be differently implemented according to the polarities of the input signals.

What is claimed is:

1. An internal voltage generating circuit, comprising:
a normal reference voltage generating unit configured to generate a normal reference voltage having a constant voltage level without regard to process, voltage, and temperature (PVT) variations;
a test reference voltage generating unit configured to generate a test reference voltage by dividing a voltage level between an external power supply voltage and the normal reference voltage at a set ratio; and
an internal voltage generating unit configured to generate an internal voltage in response to the test reference voltage.

2. The internal voltage generating circuit of claim 1, wherein the internal voltage generating unit is configured to generate a boosted test voltage as the internal voltage by performing a charge pumping operation based on a level of the test reference voltage.

3. The internal voltage generating circuit of claim 1, wherein the test reference voltage generating unit comprises:
a test voltage generating unit configured to receive the normal reference voltage and generate a test voltage having the same level as the normal reference voltage; and
a voltage dividing unit configured to determine the level of the test reference voltage by dividing a voltage level between the external power supply voltage and the test voltage at the set ratio in response to a test signal.

4. The internal voltage generating circuit of claim 3, wherein the voltage dividing unit comprises a switch and first and second resistors, which are coupled in series between terminals supplying the external power supply voltage and the test voltage, respectively,
wherein the switch is controlled to be turned on/off in response to the test signal, and
wherein the test reference voltage is outputted at a connection node of the first resistor and the second resistor.

5. The internal voltage generating circuit of claim 2, wherein the internal voltage generating unit comprises:
a voltage level detecting unit configured to detect a level of the boosted test voltage based on the level of the test reference voltage;
an oscillating unit configured to generate an oscillation signal toggling at a set frequency in response to an output signal of the voltage level detecting unit; and
a charge pumping unit configured to change the level of the boosted test voltage by performing the charge pumping operation in response to the oscillation signal.

6. The internal voltage generating circuit of claim 1, wherein a level of the normal reference voltage is higher than a level of a ground voltage.

7. The internal voltage generating circuit of claim 1, further comprising:
an operation reference voltage generating unit configured to generate an operation reference voltage by selecting one of the normal reference voltage and the test reference voltage in response to a test signal.

8. The internal voltage generating circuit of claim 7, wherein the operation reference voltage generating unit comprises:
a voltage selection outputting unit configured to receive the normal reference voltage and the test reference voltage, output the normal reference voltage in a deactivated period of the test signal, and output the test reference voltage in an activated period of the test signal; and
an operation reference voltage outputting unit configured to generate the operation reference voltage having the same level as an output voltage of the voltage selection outputting unit.

9. The internal voltage generating circuit of claim 7, wherein the internal voltage generating unit is configured to generate the internal voltage by performing a charge pumping operation based on a level of the operation reference voltage.

10. The internal voltage generating circuit of claim 9, wherein the internal voltage generating unit comprises:
a voltage level detecting unit configured to detect a level of the internal voltage based on the level of the operation reference voltage;
an oscillating unit configured to generate an oscillation signal toggling at a set frequency in response to an output signal of the voltage level detecting unit; and
a charge pumping unit configured to change the level of the internal voltage by performing the charge pumping operation in response to the oscillation signal.

11. The internal voltage generating circuit of claim 7, wherein the internal voltage generating unit comprises:
a voltage level detecting unit configured to detect a level of the internal voltage based on the level of the operation reference voltage; and
a voltage down converting unit configured to change the level of the internal voltage by supply the external power supply voltage a terminal of the internal voltage in response to an output signal of the voltage level detecting unit.

12. A testing method of an integrated circuit, comprising:
generating a normal reference voltage having a constant voltage level without regard to process, voltage, and temperature (PVT) variations;
generating a test reference voltage having an initial level of the normal reference voltage as an initial value and varying by a level variation width obtained by dividing a level variation width of an external power supply voltage at a set ratio;
generating a boosted test voltage by performing a charge pumping operation based on a level of the test reference voltage;
performing an early fail rate (EFR) test operation using the boosted test voltage; and
performing a test during burn in (TDBI) test operation using the boosted test voltage.

13. The testing method of claim 12, wherein the generating of the test reference voltage comprises:
setting the normal reference voltage as the initial value of the test reference voltage; and
outputting the test reference voltage by dividing a level difference between the external power supply voltage and the normal reference voltage at the set ratio.

14. The testing method of claim 12, wherein the generating of the boosted test voltage comprises:
detecting a level of the boosted test voltage based on the level of the test reference voltage;
generating an oscillation signal toggling a set frequency in response to the detection result; and
changing the level of the boosted test voltage by performing the charge pumping operation in response to the oscillation signal.

15. The testing method of claim 12, wherein the boosted test voltage varies by a smaller level variation width during the EFR test operation than the TDBI test operation.

16. The testing method of claim 12, wherein a level of the normal reference voltage is higher than a level of a ground voltage.

17. An internal voltage generating circuit, comprising:
a main reference voltage generating unit configured to generate a main reference voltage;
a sub reference voltage generating unit configured to generate a first sub reference voltage by dividing the main reference voltage at a first set ratio and generate a second sub reference voltage by dividing the main reference voltage at a second set ratio;
a test reference voltage generating unit configured to generate a first test reference and a second test reference voltage in response to the first sub reference voltage and the second sub reference voltage, respectively;
an operation reference voltage generating unit configured to generate a first operation reference voltage in response to one of the first sub reference voltage and the first test reference voltage and generate a second operation reference voltage in response to one of the second sub reference voltage and the second test reference voltage;
a first internal voltage generating unit configured to generate a first internal voltage based on a level of the first operation reference voltage; and
a second internal voltage generating unit configured to generate a second internal voltage based on a level of the second operation reference voltage.

18. The internal voltage generating circuit of claim 17, wherein the first test reference voltage is generated by dividing a voltage level between an external power supply voltage and the first sub reference voltage at a first test ratio, and the second test reference voltage is generated by dividing a voltage level between the external power supply voltage and the second sub reference voltage at a second test ratio.

19. The internal voltage generating circuit of claim 18, wherein the first internal voltage is generated by performing a charge pumping operation based on the level of the first operation reference voltage, and the second initial voltage is generated by performing a voltage down converting operation based on the level of the second operation reference voltage.
